(19) United States
(12) Patent Application Publication
(10) Pub. No.: US 2013/0283611 A1
(43) Pub. Date: Oct. 31, 2013

(54) THERMOELECTRIC MODULE

(71) Applicant: Yamaha Corporation, Hamamatsu-Shi (JP)

(72) Inventor: Hidetoshi Yasutake, Shizuoka-Ken (JP)

(73) Assignee: Yamaha Corporation, Hamamatsu-Shi (JP)

(21) Appl. No.: 13/895,588

(22) Filed: May 16, 2013

Related U.S. Application Data
(62) Division of application No. 11/567,090, filed on Dec. 5, 2006, now abandoned.

(30) Foreign Application Priority Data
Dec. 7, 2005 (JP) 2005-353659

(51) Int. Cl. H05K 3/46

(52) U.S. Cl. CPC H05K 3/46
USPC 29/846

(57) ABSTRACT

A thermoelectric module may include a first substrate having a mounting portion and an extension portion and a second substrate facing to the mounting portion. First electrodes are disposed on the mounting portion and have a first surface layer of gold. Second electrodes are disposed on the second substrate and have a second surface layer of gold. Thermoelectric elements are electrically bonded between the first and second arrays of electrodes by solder. A bonding layer is disposed on the extension portion and has a third surface layer of gold. The first surface layer of gold is distanced by a gap from the first surface layer of gold. A metal layer underlies the gap. The metal layer has a solder-wettability that is lower than that of the first and third surface layers of gold.

### CROSS REFERENCE

This application is a divisional of U.S. patent application Ser. No. 11/567,090 filed Dec. 5, 2006, which claims priority to JP2005-353659 filed on Dec. 7, 2005. The disclosures of these application are incorporated herein by reference.

### BACKGROUND OF THE INVENTION

1. Field of the Invention

The present invention generally relates to a thermoelectric module having a bonding portion.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

A thermoelectric module utilizing the Peltier effect has been known. The thermoelectric module includes one or more substrates or printed boards, and one or more thermoelectric elements that are mounted and fixed to the substrate or printed board by using a solder.

Japanese Unexamined Patent Application, First Publication, No. 5-102648 discloses a conventional thermoelectric module including a printed board that has a solder flow stopper that restricts or prevents solder from flowing beyond a limited area, to which each thermoelectric conversion element is bonded. The solder flow stopper is provided between a first area on which a larger capacitor is mounted and a second area on which a smaller capacitor is mounted. The solder flow stopper is formed of a solder resist. In general, the solder resist has a low heat resistant temperature or low thermal stability. The solder resist is expensive. The printed board does not need to have high heat stability. Thus, the solder reflow stopper of the solder resist can be provided on the printed board.

The substrate for the thermoelectric module needs to have high thermal stability at high temperature, for example, a temperature of at least 400° C. As described above, the solder flow stopper formed of the solder resist has low thermal stability. Thus, the solder flow stopper is not useful to the substrate that is subjected to heat treatment at high temperature.

As described above, the solder resist is expensive. Providing the solder flow stopper of the expensive solder resist on the substrate increases the manufacturing cost of the substrate.

In view of the above, it will be apparent to those skilled in the art from this disclosure that there exists a need for an improved thermoelectric module. This invention addresses this need in the art as well as other needs, which will become apparent to those skilled in the art from this disclosure.

### SUMMARY OF THE INVENTION

Accordingly, it is a primary object of the present invention to provide a thermoelectric module that has a solder flow restricting structure that has high thermal stability.

It is another object of the present invention to provide a thermoelectric module that has an adequate bonding structure between the thermoelectric element and the substrate.

It is a further object of the present invention to provide a thermoelectric module that exhibit desired performances.

In accordance with a first aspect of the present invention, a thermoelectric module may include: a first substrate having a mounting portion and an extension portion; first electrodes disposed on the mounting portion, the first electrodes having a first surface layer of gold; a second substrate that faces to the mounting portion, the second substrate being distanced from the first substrate; second electrodes disposed on the second substrate, the second electrodes having a second surface layer of gold; a plurality of thermoelectric elements electrically bonded between the first and second arrays of electrodes by solder; at least one bonding layer disposed on the extension portion, the at least one bonding layer having a third surface layer of gold, the first surface layer of gold being distanced by a gap from the first surface layer of gold; and a metal layer underlying the gap, the metal layer having a solder-wettability that is lower than that of the first and third surface layers of gold.

Preferably, the gap may have a width of at least 5 micrometers.

Preferably, the first surface layer of gold may have a larger size than that of the thermoelectric element.

In accordance with a second aspect of the present invention, a thermoelectric module may include, but is not limited to, a first substrate; a second substrate; a first conductive pattern disposed on the first substrate; a second conductive pattern disposed on the second substrate; a thermoelectric element disposed between the first and second conductive patterns, the thermoelectric element being bonded to the first and second conductive patterns by a solder; a third conductive pattern disposed on the first substrate; and a solder-flow inhibitor disposed between the first and third conductive patterns, the solder-flow inhibitor being configured to inhibit a solder flow to the third conductive pattern from the first conductive pattern.

Preferably, the solder-flow inhibitor may be configured to separate surfaces of the first and third conductive patterns from each other.

Preferably, the solder-flow inhibitor may be configured to have a lower-solder-wettability surface having a solder-wettability that is lower than that of the surface of the first conductive pattern.

Preferably, the solder-flow inhibitor may include a surface-separator and a lower-solder-wettability surface. The surface-separator may be configured to separate surfaces of the first and third conductive patterns from each other. The lower-solder-wettability surface may have a solder-wettability that is lower than that of the surface of the first conductive pattern.

Preferably, the surface-separator may have an empty-space that separates surfaces of the first and third conductive patterns from each other. The empty-space may extend over the lower-solder-wettability surface.

Preferably, the solder-flow inhibitor further may include an underlying conductive layer that underlies the first and third patterns and the empty-space. The underlying conductive layer may be lower in solder-wettability than the first and third conductive patterns.

Preferably, the first and third patterns may include gold layers. The underlying conductive layer may include a metal layer that is lower in solder-wettability than the gold layer.

Preferably, the surface-separator may have a dimension of at least 3 micrometers. The dimension is defined between the first and third conductive patterns.

Preferably, the first conductive pattern may have a larger size than the thermoelectric element.

Preferably, the first and second conductive patterns serve as electrodes and the third conductive pattern serves as a bonding pattern.

### BRIEF DESCRIPTION OF THE DRAWINGS

Referring now to the attached drawings which form a part of this original disclosure:

FIG. 1 is a schematic perspective view illustrating a thermoelectric module in accordance with a first preferred embodiment of the present invention;

FIG. 2 is a plan view illustrating the thermoelectric module shown in FIG. 1;

FIG. 3 is a cross sectional elevation view illustrating the thermoelectric module, taken along a 3-3 line of FIG. 2;

FIG. 4 is a fragmentary cross sectional elevation view illustrating an extension portion of a first substrate included in the thermoelectric module shown in FIGS. 1 through 3;

FIG. 5 is a fragmentary cross sectional elevation view illustrating a first step involved in a process for forming the extension portion of the first substrate included in the thermoelectric module shown in FIGS. 1 through 3.

FIG. 6 is a fragmentary cross sectional elevation view illustrating a second step involved in a process for forming the extension portion of the first substrate included in the thermoelectric module shown in FIGS. 1 through 3.

FIG. 7 is a fragmentary cross sectional elevation view illustrating a third step involved in a process for forming the extension portion of the first substrate included in the thermoelectric module shown in FIGS. 1 through 3.

FIG. 8 is a fragmentary cross sectional elevation view illustrating a fourth step involved in a process for forming the extension portion of the first substrate included in the thermoelectric module shown in FIGS. 1 through 3.

FIG. 9 is a fragmentary cross sectional elevation view illustrating a fifth step involved in a process for forming the extension portion of the first substrate included in the thermoelectric module shown in FIGS. 1 through 3.

FIG. 10 is a fragmentary cross sectional elevation view illustrating a sixth step involved in a process for forming the extension portion of the first substrate included in the thermoelectric module shown in FIGS. 1 through 3.

FIG. 11 is a fragmentary cross sectional elevation view illustrating a first substrate that includes a first electrode, a groove and a bonding layer shown in FIG. 10.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

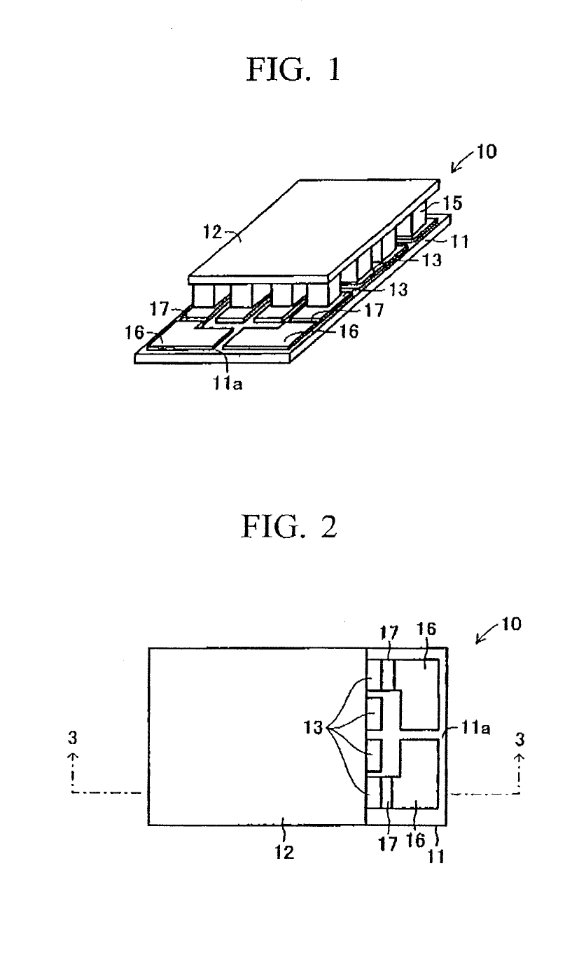

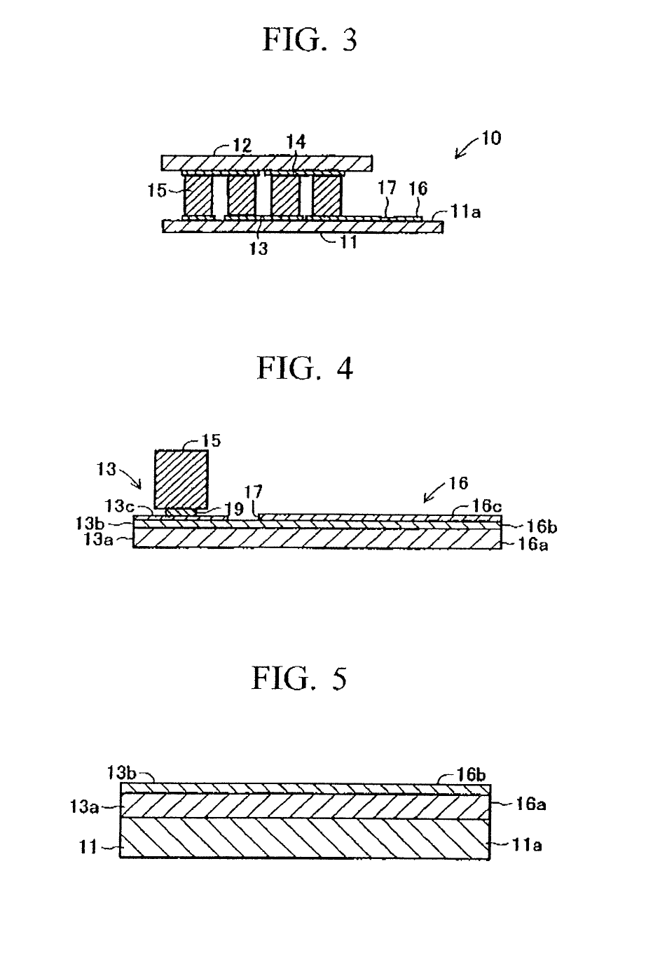

FIG. 1 is a schematic perspective view illustrating a thermoelectric module in accordance with a first preferred embodiment of the present invention. FIG. 2 is a plan view illustrating the thermoelectric module shown in FIG. 1. FIG. 3 is a cross sectional elevation view illustrating the thermoelectric module, taken along a 3-3 line of FIG. 2. A thermoelectric module 10 may include, but is not limited to, a pair of first and second substrates 11 and 12, and a plurality of thermoelectric elements 14. The first and second substrates 11 and 12 can be realized by insulating substrates. A typical example of insulating material for the first and second substrates 11 and 12 may include, but is not limited to, alumina.

In a case, the first substrate 11 may have a larger size or dimension than the second substrate 12. The first substrate 11 has a primary portion and a secondary portion. The first and second substrates 11 and 12 may be aligned relative to each other so that the primary portion of the first substrate 11 overlaps, in plan view, the second substrate 12, while the secondary portion thereof does not overlap the second substrate 12. The primary portion of the first substrate 11 provides a mounting area for mounting the plurality of thermoelectric elements 15. The secondary portion of the first substrate 11 serves as an extension portion 11a that provides a bonding area.

A typical example of the first and second substrates 11 and 12 may have, but is not limited to, a rectangular shape. In this case, the first substrate 11 has a first length and a first width. The second substrate 12 has a second length and a second width. The first width may be substantially identical to the second width, and the first length may be longer than the second length. As described above, the first and second substrates 11 and 12 may be aligned relative to each other so that the second substrate 12 overlaps the primary portion of the first substrate 11, while the extending portion 11a is not covered by the second substrate 12.

The first substrate 11 may have a plurality of first electrodes 13. The second substrate 12 may have a plurality of second electrodes 14. In a case, the plurality of first electrodes 13 may be disposed in a first matrix array. The plurality of second electrodes 14 may be disposed in a second matrix array. Adjacent two of the first electrodes 13 are distanced from each other. Adjacent two of the second electrodes 14 are also distanced from each other. The first and second matrix arrays are displaced relative to each other in the lengthwise direction of the first and second substrates 11 and 12. In a case, the first and second electrodes 13 and 14 may have a rectangular shape, and substantially uniform dimensions. In this case, the magnitude of displacement between the first and second matrix arrays may be approximately a half of the dimension of the first and second electrodes 13 and 14.

The plurality of thermoelectric elements 15 is disposed so as to form a third matrix array and is interposed between the first and second electrodes 13 and 14. The plurality of thermoelectric elements 15 is bonded to the first and second electrodes 13 and 14, so that the first and second electrodes 13 and 14 are electrically connected to each other through the thermoelectric elements 15. Adjacent two of the thermoelectric elements 15 are distanced from each other. The dimensions of each of the first and second electrodes 13 and 14 are determined so as to allow adjacent two of the thermoelectric elements 15 to be mounted on each of the first and second electrodes 13 and 14. Typically, the first and second electrodes 13 and 14 may have a dimension in the lengthwise direction, wherein the dimension is greater than the double of a size of the thermoelectric element 15 so that adjacent two of the thermoelectric elements 15 are bonded to the first electrode 13 or the second electrode 14.

Adjacent two of the thermoelectric elements 15, both of which are distanced from each other, may be bonded either between one of the first electrodes 13 and adjacent two of the second electrodes 14 or between adjacent two of the first electrodes 13 and one of the second electrodes 14. For example, first, second and third ones of the thermoelectric elements 15 are aligned in turn at a constant pitch in the lengthwise direction of the first and second substrates 11 and 12. The first and second ones of the thermoelectric elements 15 are adjacent to each other. The second and third ones of the thermoelectric elements 15 are adjacent to each other. The first and second ones of the thermoelectric elements 15 may be bonded to one of the first electrodes 13 and adjacent two of the second electrodes 14. The second and third ones of the thermoelectric elements 15 may be bonded to adjacent two of the first electrodes 13 and one of the second electrodes 14.

Bonding the thermoelectric elements 15 to the first and second electrodes 13 and 14 can be realized by using solder. The plurality of thermoelectric elements 15 may be realized by P-type and N-type thermoelectric elements 15 that are disposed alternately. In other words, the P-type thermoelectric element may be adjacent to the N-type thermoelectric elements. A typical example of the thermoelectric elements 15 may be formed of, but is not limited to, a bismuth-tellurium based alloy. The P-type and N-type thermoelectric elements may have compositions of Bi and Te. The P-type and N-type thermoelectric elements compositional ratios may have a slightly different compositional ratio. A typical example of each shape of the first and second electrodes 13 and 14 may include, but is not limited to, a rectangle. A typical example of the shape of the thermoelectric element 15 may be, but is not limited to, a rectangular parallelepiped.

As described above, the first substrate 11 includes the extension portion 11a. The extension portion 11a may include, but is not limited to, at least a bonding layer, and at least a solder-flow inhibitor. The solder-flow inhibitor is disposed between the bonding layer and at least one selected from the first electrodes 13. The solder-flow inhibitor is configured to inhibit a solder flow to a surface of the bonding layer from the surface of the at least one selected from the first electrodes 13. Typically, the solder-flow inhibitor may be realized by at least one of a surface-separator and a surface having a solder-wettability that is lower than those of the surfaces of the bonding layer and the first electrodes 13. The surface having the lower solder-wettability will hereinafter be referred to as a lower solder-wettability surface. The lower solder-wettability surface may inhibit the solder flow to the surface of the bonding layer from the surface of the at least one selected from the first electrodes 13. The surface-separator is configured to separate the surface of the bonding layer from the surface of the at least one selected from the first electrodes 13. The surface-separator may inhibit the solder flow to the surface of the bonding layer from the surface of the at least one selected from the first electrodes 13. Typical examples of the surface-separator may include, but are not limited to, a gap, a slit, a groove, a depressed portion, a concave portion, a projecting portion, a convex portion, a wall structure, a bar, and a column.

In some case, the solder-flow inhibitor may be realized by a combination of the lower solder-wettability surface and the surface-separator. In one case, the solder-flow inhibitor may be realized by a gap or a slit defined by one or more walls that provide the lower solder-wettability surface. In another case, the solder-flow inhibitor may be realized by a groove, a depressed portion, or concave portion that is defined by one or more walls providing the lower solder-wettability surface. In still another case, the solder-flow inhibitor may be realized by a projecting portion, a convex portion, a wall structure, a bar, or a column that is defined by one or more walls providing the lower solder-wettability surface.

In a typical case, as shown in FIGS. 1 and 2, the solder-flow inhibitor may be realized by a combination of grooves that have bottom surfaces providing the lower solder-wettability surface. For example, the extension portion 11a includes a pair of bonding layers 16 that extends from selected two of the first electrodes 13. The selected two of the first electrodes 13 may typically be positioned on outside alignments of the third matrix array, and be proximal to the extension portion 11a. The outside alignments extend in the lengthwise direction of the first substrate 11. The grooves 17 may extend approximately in the widthwise direction of the first substrate 11. The bonding layer 16 has a surface that provides a bonding area. The extension portion 11a also includes grooves 17 as surface-separators that separate the surfaces of the bonding layers 16 from the surface of the selected two of the first electrodes 13. Each of the grooves 17 has a bottom portion that provides a solder-wettability surface that is lower in solder-wettability than the surfaces of the bonding layers 16 and the surfaces of the first electrodes 13.

In a typical case, each of the bonding layers 16 and each of the selected two of the first electrodes 13 may be realized by the following multi-layered structure. FIG. 4 is a fragmentary cross sectional elevation view illustrating the extension portion 11a of the first substrate 11 included in the thermoelectric module shown in FIGS. 1 through 3.

As described above, the first matrix array of the first electrodes 13 is disposed on the mounting area of the primary portion of the first substrate 11. The second matrix array of the second electrodes 14 is disposed on the second substrate 12. The bonding layers 16 are disposed on the extension portion 11a of the first substrate 11. The first electrodes 13 are distanced from each other. As shown in FIG. 4, the selected two of the first electrodes 13 may be continued to the bonding layers 16. The grooves 17 may be formed between the selected two of the first electrodes 13 and the bonding layers 16 so that the grooves 17 separate the surfaces of the selected two of the first electrodes 13 from the surfaces of the bonding layers 16. In some cases, the first and second electrodes 13 and 14 and the bonding layers 16 may have multi-layered structures. The multi-layered structures may include, but are not limited to, three metal layers such as a copper layer, a nickel layer, and a gold layer.

In a case, each of the first electrodes 13 may be formed by a copper layer 13a, a nickel layer 13b, and a gold layer 13c. The copper layer 13a may be disposed on the primary portion of the first electrode 11. The copper layer 13a may have a thickness of 50 micrometers. The nickel layer 13b may be disposed on the copper layer 13a. The nickel layer 13b may have a thickness of 4 micrometers. The gold layer 13c may be disposed on the nickel layer 13b. The gold layer 13c provides the surface of the first electrode 13. The gold layer 13c may have a thickness of 0.3 micrometers. Each of the second electrodes 14 may have the same multi-layered structure as the first electrodes 13.

Each of the bonding layers 16 may be formed by a copper layer 16a, a nickel layer 16b, and a gold layer 16c. The copper layer 16a may be continued to the copper layer 13a included in the selected two of the first electrodes 13. In other words, the copper layers 13a and 16a may be parts of a single copper layer. The copper layer 16a is disposed on the extension portion 11a of the first substrate 11. The copper layer 16a may have a thickness of 50 micrometers. The nickel layer 16b may be continued to the nickel layer 13b included in the selected two of the first electrodes 13. In other words, the nickel layers 16b and 13b may be parts of a single nickel layer. The nickel layer 16b is disposed on the copper layer 16a. The nickel layer 16b may have a thickness of 4 micrometers. The gold layer 16c is discontinued or separated from the gold layer 13c by the groove 17. The gold layer 16c is disposed on the nickel layer 16b. The gold layer 16c may have a thickness of 1 micrometer. The gold layer 16c provides the surface of the bonding layer 16.

The groove 17 extends between the gold layers 16c and 13c so that the groove 17 separates the gold layers 16c and 13c from each other. In other words, the groove 17 separates the surface of the bonding layer 16 from the surface of the first electrode 13. In still other words, the groove 17 may provide a gap or a slit that separates the gold layers 16c and 13c from each other. The groove 17 may extend in the widthwise direction of the first substrate 11. The groove 17 may have a thickness of at least 3 micrometers, and preferably 5 micrometers, and typically 10-50 micrometers. The increase in the width of the groove 17 causes increase in the size or dimension of the thermoelectric module 10. The maximum width of the groove 17 can be decided by taking into account a maximum allowable size or dimension of the thermoelectric module 10. For example, the width of the groove 17 may be greater than 50 micrometers, for example, 100 micrometers or more.

A solder paste layer 19 may be provided on the gold layer 13c. The thermoelectric element 15 is bonded through the solder paste layer 19 to the gold layer 13c of the first electrode 13.

FIGS. 5 through 10 are fragmentary cross sectional elevation views illustrating sequential steps involved in a process for forming the extension portion 11a of the first substrate 11 included in the thermoelectric module shown in FIGS. 1 through 3.

As shown in FIG. 5, the copper layers 16a and 13a are provided on the first substrate 11 so that the copper layer 13a extends over the primary portion of the first substrate 11 and the copper layer 16a extends over the extension portion 11a of the first substrate 11. The copper layers 16a and 13a can be formed of a single copper layer. The nickel layers 16b and 13b are provided on the copper layers 16a and 13a, respectively. The nickel layers 16b and 13b can be formed of a single nickel layer.

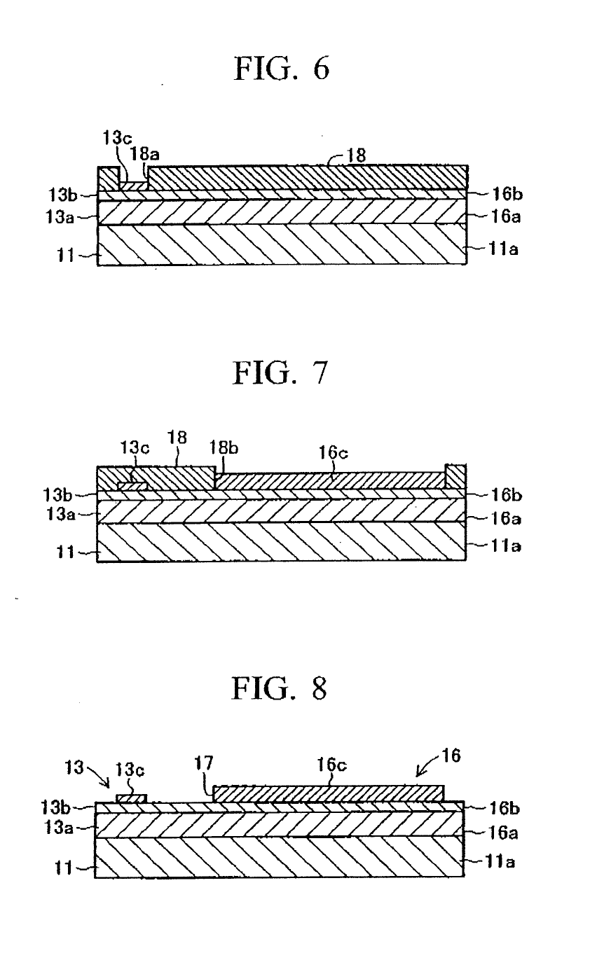

As shown in FIG. 6, a resist layer 18 is formed, which extends over the nickel layers 16b and 13b. The resist layer 18 is then selectively removed so as to form openings 18a that is positioned on first selected regions of the surface of the nickel layer 13b. The surface of the nickel layer 13b is partially shown through the openings 18a. The gold layers 13c are formed in the openings 18a so that the gold layers 13c are formed on the first selected regions of the surface of the nickel layer 13b. The gold layers 13c can be formed by a plating process.

As shown in FIG. 7, the resist layer 18 is removed. A new resist layer 18 is formed, which extends over the nickel layers 16b and 13b and the gold layers 13c. The new resist layer 18 is then selectively removed so as to form openings 18b that is positioned on second selected regions of the surface of the nickel layer 16b. The surface of the nickel layer 16b is partially shown through the openings 18b. The gold layers 16c are formed in the openings 18b so that the gold layers 16c are formed on the second selected regions of the surface of the nickel layer 16b. The gold layers 16c can be formed by a plating process.

As shown in FIG. 8, the new resist layer 18 is removed. The gold layers 13c are distanced from the gold layers 16c by a gap that provides the groove 17. The groove 17 is defined between the gold layers 13c and 16c. The bottom of the groove 17 is defined by the surface of the nickel layers 13b and 16b. The first electrodes 13 and the bonding layers 16 are formed. The first electrodes 13 and the bonding layers 16 are electrically connected to each other.

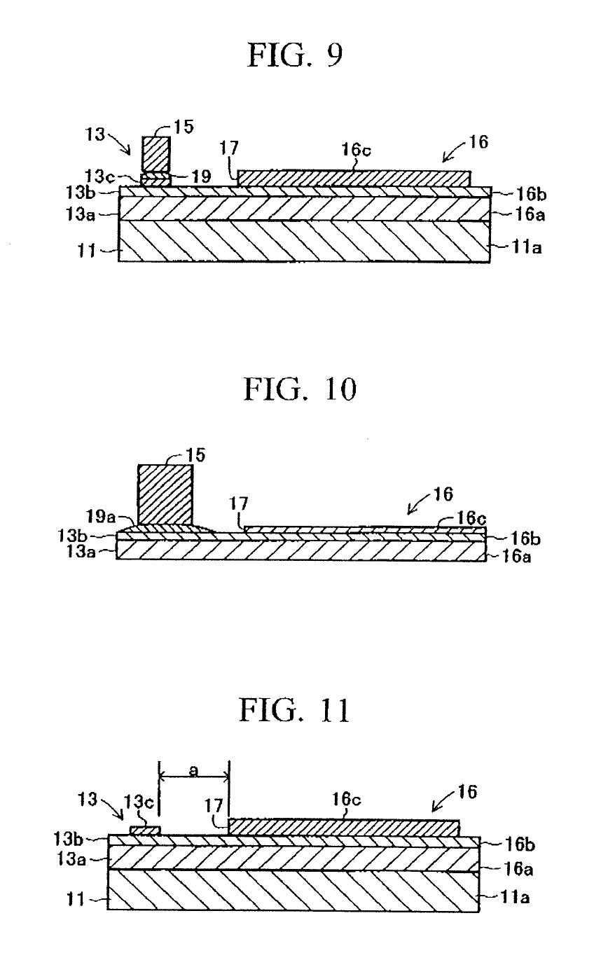

As shown in FIG. 9, a solder paste is selectively applied on the gold layers 13c so that the solder paste layers 19 are formed on the gold layers 13c. In other words, the solder paste layers 19 are formed on the first electrodes 13. Even illustrations are omitted, the second electrodes 14 having the same multi-layered structure are formed on the second substrate 12. Another solder paste is also selectively applied on the surfaces of the second electrodes 14 so that the solder paste layers are also formed on the second electrodes 14.

The thermoelectric elements 15 are placed on the solder paste layers 19. The thermoelectric elements 15 are distanced from each other. The first and second electrodes 13 and 14 may be slightly larger in size than the thermoelectric elements 15.

The second substrate 12 is placed over the first substrate 11 so that the thermoelectric elements 15 are interposed between the first and second substrates 11 and 12. The thermoelectric elements 15 are made into contact with the solder paste layers 19 on the first and second electrodes 13 and 14.

As shown in FIG. 10, the first and second substrates 11 and 12 sandwiching the thermoelectric elements 15 are then heated by a heater so that the solder paste layers 19 are melt. The gold layers 13c and the solder paste layers 19 are alloyed to form alloyed connection portions 19a between the thermoelectric elements 15 and the nickel layers 13b of the first electrodes 11. Similarly, the same alloyed connection portions are formed between the thermoelectric elements 15 and the nickel layers of the second electrodes 12.

The first and second substrates 11 and 12 are picked up from the heater and cooled down so that the alloyed connection portions 19a are solidified, thereby obtaining the thermoelectric module 10 shown in FIGS. 1 through 3.

Post electrodes or wirings are bonded to the bonding layers 16 using solder. As described above, the bonding layers 16 are electrically connected to the first electrodes 13. The thermoelectric elements 15 are electrically connected to the first electrodes 13. Thus, the bonding layers 16 are electrically connected to the thermoelectric elements 15. The post electrodes or wirings are also electrically connected to the thermoelectric elements 15.

As described above, the groove 17 separates the surface of the gold layer 13c of the first electrode 13 from the surface of the gold layer 16c of the bonding layer 16. Namely, the groove 17 serves as a surface-separator. The groove 17 may also provide a gap between the gold layers 13c and 16c. The gap or surface-separation that is provided by the groove 17 inhibits the flow of solder to the gold layer 16c of the bonding layer 16 from the gold layer 13c of the first electrode 13.

The groove 17 has the bottom surface that is a part of the nickel layer 13b or 16b. The nickel layers 13b and 16b have a solder-wettability that is lower than the gold layers 13c and 16c. Thus, the bottom of the groove 17 provides the lower solder-wettability that inhibits the flow of solder. The bottom of the groove 17 inhibits the flow of solder to the gold layer 16c of the bonding layer 16 from the gold layer 13c of the first electrode 13.

The width of at least 3 micrometers, preferably 5 micrometers, is highly effective to inhibit the flow of solder to the gold layer 16c of the bonding layer 16 from the gold layer 13c of the first electrode 13.

The gold layer 13c has a larger size than that of the thermoelectric element 15 so that the edges of the thermoelectric element 15 are positioned inside the periphery of the gold layer 13c. This contributes to avoid the solder to over-flow from the gold layer 13c.

The test for confirming the solder flow from the first electrode 13 toward the bonding layer 16 was carried out for a variety of width of the groove 17. FIG. 11 is a fragmentary cross sectional elevation view illustrating the first substrate 11 that includes the first electrode 13, the groove 17 and the bonding layer 16. The groove 17 has a width “a”. The test was carried out by changing the width “a” from 1 micrometer to 50 micrometers. If the solder flow reaches the gold layer 16c of the bonding layer 16, then this means the thermoelectric module 10 is defective. If the solder flow does not reach the gold layer 16c of the bonding layer 16, then this means the thermoelectric module 10 is non-defective.

In each of Examples 1-5, and Comparative Example 1, 48 samples of the thermoelectric modules 10 were prepared.

In Example 1, the first type of the thermoelectric modules 10 was prepared, which have the groove width of 3 micrometers. 48 samples of the first type of the thermoelectric modules 10 were examined. It was confirmed that the yield of the first type of the thermoelectric modules 10 is 89%.

In Example 2, the second type of the thermoelectric modules 10 was prepared, which have the groove width of 5 micrometers. 48 samples of the second type of the thermoelectric modules 10 were examined. It was confirmed that the yield of the second type of the thermoelectric modules 10 is 100%.

In Example 3, the third type of the thermoelectric modules 10 was prepared, which have the groove width of 10 micrometers. 48 samples of the third type of the thermoelectric modules 10 were examined. It was confirmed that the yield of the third type of the thermoelectric modules 10 is 100%.

In Example 4, the fourth type of the thermoelectric modules 10 was prepared, which have the groove width of 30 micrometers. 48 samples of the fourth type of the thermoelectric modules 10 were examined. It was confirmed that the yield of the fourth type of the thermoelectric modules 10 is 100%.

In Example 5, the fifth type of the thermoelectric modules 10 was prepared, which have the groove width of 50 micrometers. 48 samples of the fifth type of the thermoelectric modules 10 were examined. It was confirmed that the yield of the fifth type of the thermoelectric modules 10 is 100%.

In Comparative Example 1, the conventional type of the thermoelectric modules was prepared, which has no groove. 48 samples of the conventional type of the thermoelectric modules 10 were examined. It was confirmed that the yield of the conventional type of the thermoelectric modules 10 is 0%.

As can be seen from Examples 1-5 and Comparative Example 1, the width of at least 3 micrometers is highly effective to inhibit the solder flow from reaching the gold layer 16c of the bonding layer 16. The width of at least 5 micrometers securely prevents the solder flow from reaching the gold layer 16c of the bonding layer 16.

The first and second substrates 11 and 12 may be realized by the insulating substrates. Examples of the material for the first and second substrates 11 and 12 may include, but are not limited to, any types of insulating or semi-insulating materials, such as alumina, aluminum nitride, silicon carbide, and silicon nitride. The first and second substrates 11 and 12 may also be realized by a conductive substrate that has an insulating surface. Typical examples of the first and second substrates 11 and 12 may include, but are not limited to, surface-insulated metal substrates.

The first and second electrodes 13 and 14 and the bonding layers 16 may also be modified as long as the underlying layer that underlies the surface layer has a poorer solder-wettability than that of the surface layer. The grooves 17 may be modified as long as the groove 17 provides a surface that has a poorer solder-wettability than that of the surfaces of the first electrodes 13 and the bonding layers 16.

The elements used for the thermoelectric module 10 can also be modified in material, shape and size or dimension.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1-13. (canceled)

14. A method of manufacturing a thermoelectric module having a first substrate having a primary portion and an extension portion, a second substrate, and a plurality of thermoelectric elements, wherein the first and second substrates comprise copper and nickel layers, the method comprising:
forming a first resist layer over the nickel layer of the first substrate;
selectively removing the first resist layer in the primary portion of the first substrate to form a plurality of first openings in the first resist layer;
plating first gold layers in the plurality of first openings;
removing the first resist layer to expose the nickel layer of the first substrate;
forming a second resist layer over the exposed nickel layer and first gold layers;
selectively removing the second resist layer in the extension portion of the first substrate to form a plurality of second openings in the second resist layer;
plating second gold layers in the plurality of second openings;
removing the second resist layer;
wherein a gap is formed between the first gold layers and the second gold layers.

15. The thermoelectric module according to claim 14, wherein the gap has a width of at least 3 micrometers.

16. The thermoelectric module according to claim 15, wherein the gap has a width of at least 5 micrometers.

17. The method of manufacturing a thermoelectric module of claim 14, further comprising providing third gold layers on the nickel layer of the second substrate.

18. The method of manufacturing a thermoelectric module of claim 17, further comprising:
applying first and second solder paste layers to the first and third gold layers respectively;
placing thermoelectric elements between the first and second solder paste layers;
heating and melting the first and second solder paste layers to form first and second alloyed layers comprising the first and third gold layers and the first and second solder paste layers respectively, thereby forming an alloyed connection between the thermoelectric elements and the first and second nickel layers; and
cooling the first and second alloyed layers so that the alloyed connections are solidified.

19. The method of manufacturing a thermoelectric module of claim 18, further comprising positioning the thermoelectric elements inside a periphery of the first and third gold layers.

20. The method of manufacturing a thermoelectric module of claim 19, further comprising bonding wirings to second gold layers using solder.

21. The method of manufacturing a thermoelectric module of claim 20, wherein the gap prevents solder from electrically connecting the first gold layers to the second gold layers.

22. The method of claim 17, wherein providing third gold layers comprises:
forming a third resist layer over the nickel layer of the second substrate;
selectively removing the third resist layer to form a plurality of third openings in the third resist layer; and
plating third gold layers in the plurality of third openings.
